(19) United States
(12) Patent Application Publication
(10) Pub. No.: US 2024/0266848 A1
(43) Pub. Date: Aug. 8, 2024

(54) CHARGING DEVICE

(71) Applicant: TOYOTA JIDOSHA KABUSHIKI KAISHA, Toyota-shi (JP)

(72) Inventors: Toshihiro YONEDA, Toyota-shi (JP); Kotaro ASABA, Nagoya-shi (JP)

(73) Assignee: TOYOTA JIDOSHA KABUSHIKI KAISHA, Toyota-shi (JP)

(21) Appl. No.: 18/400,121

(22) Filed: Dec. 29, 2023

(30) Foreign Application Priority Data
Feb. 3, 2023 (JP) 2023-015289

(51) Int. Cl. H02J 7/00; G01R 31/52

(52) U.S. Cl. CPC H02J 7/0031; G01R 31/52; H02J 7/00718

(57) ABSTRACT

The charging device includes a BT first/second terminal, a PS first/second terminal, a first/second power line, a bypass power line, and an earth leakage detector. When the first/second power line is passing through and the sum of the currents flowing through the first/second power line is other than zero, the earth leakage detector interrupts the first/second power line. The bypass power line bypasses the earth leakage detector and connects the BT second terminal to the PS first terminal. The controller disconnects the power from the PS first (second) terminal. The controller connects a battery to the BT first (second) terminal and also connects the PS first terminal and the BT second terminal through the bypass power line. If the earth leakage detector is activated, the bypass power line will be disconnected. Then, charging of the battery is started.

### CROSS-REFERENCE TO RELATED APPLICATION

This application claims priority to Japanese Patent Application No. 2023-015289 filed on Feb. 3, 2023, incorporated herein by reference in its entirety.

### BACKGROUND

### 1. Technical Field

The technique disclosed in the present specification relates to a charging device that is connected between a power source and a battery and used when charging the battery with the power source.

### 2. Description of Related Art

A charging device may be equipped with an earth leakage detector. The earth leakage detector disclosed in Japanese Unexamined Patent Application Publication No. 2022-59188 (JP 2022-59188 A) includes an earth leakage test circuit for checking whether the earth leakage detection function operates normally. The earth leakage test circuit generates a pseudo earth leakage pulse current, causes the pulse current to flow through the earth leakage detector, and checks the operation of the earth leakage detector.

### SUMMARY

A test circuit to check the operation of the earth leakage detection function is needed. However, the complexity of the test circuit increases the cost. The present specification provides a charging device that can test a leakage detection function with a simple circuit configuration.

The charging device disclosed in the present specification includes: a battery-side first terminal; a battery-side second terminal; a power source-side first terminal; a power source-side second terminal; a first power line; a second power line; a bypass power line; an earth leakage detector; and a controller. A first electrode (second electrode) of a battery is connected to the battery-side first (second) terminal. A first electrode (second electrode) of a power source is connected to the power source-side first (second) terminal. The first electrode is one of a positive electrode and a negative electrode. The second electrode is the other of the positive electrode and the negative electrode.

The first power line connects the battery-side first terminal and the power source-side first terminal. The second power line connects the battery-side second terminal and the power source-side second terminal. The first power line and the second power line pass through the earth leakage detector. The earth leakage detector shuts off the first power line and the second power line when a sum of a current flowing through the first power line and a current flowing through the second power line is other than zero. The bypass power line bypasses the earth leakage detector and connects the second electrode of the battery and the power source-side first terminal.

The controller performs the following processing. That is, the controller disconnects the power source from the power source-side first/second terminal, and connects the power source-side first terminal and the second electrode of the battery through the bypass power line. At this time, the first power line and the bypass power line are electrically connected. A closed circuit including the battery is then formed. That is, a current flows through the first power line passing through the earth leakage detector. However, no current flows through the second power line. When the earth leakage detector is normal, the earth leakage detector operates at this time. Then, the first power line and the second power line are shut off. When the earth leakage detector operates, the controller disconnects the bypass power line, restores the earth leakage detector, and connects the power source to the power source-side first terminal and the power source-side second terminal to start charging the battery. When the earth leakage detector does not operate, the controller stops charging the battery by the power source.

As described above, the charging device disclosed in the present specification uses the battery to cause current to flow through the first power line. At this time, since the bypass power line is used, no current flows through the second power line. Then, the charging device disclosed in the present specification checks an operation of the earth leakage detector. The charging device has an extremely simple circuit for checking the operation of the earth leakage detector.

Details of the techniques disclosed in the present specification and further modifications will be described in the “DETAILED DESCRIPTION OF EMBODIMENTS” below.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a circuit diagram of a charging device according to a first embodiment. Current flow during earth leakage detector test is shown;

FIG. 2 is a circuit diagram of the charging device of the first embodiment. The current flow during battery charging is shown;

FIG. 3 is a circuit diagram of a charging device according to a second embodiment. Current flow during earth leakage detector test is shown; and

FIG. 4 is a circuit diagram of a charging device according to a second embodiment. The current flow during battery charging is shown.

### DETAILED DESCRIPTION OF EMBODIMENTS

### First Embodiment

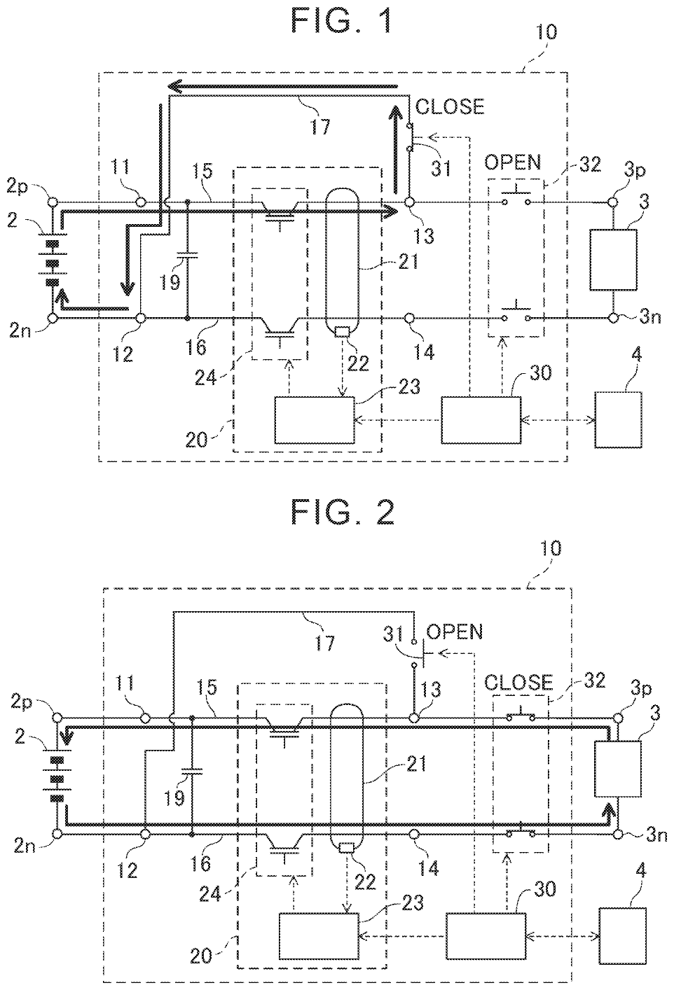

A charging device 10 according to a first embodiment will be explained with reference to FIGS. 1 and 2. 1 and 2 are circuit diagrams of the charging device 10. Charging device 10 is connected between battery 2 and DC power source 3. When the main relay 32 of the charging device 10 is closed, the DC power source 3 and the battery 2 are directly connected. Then, the battery 2 is charged with the power of the DC power source 3. Note that the DC power source 3 may be composed of an AC power source and an AC/DC converter. Furthermore, the DC power source 3 may include a boost converter that boosts the DC power. The charging device 10 may include an AC/DC converter or a boost converter.

Charging device 10 includes an earth leakage detector 20 that shuts off the power line when electric leakage is detected in the power line connecting the battery 2 and the DC power source 3. Furthermore, the charging device 10 has an earth leakage detector test function that tests whether the earth leakage detector 20 operates normally.

The charging device 10 includes four terminals (BT first terminal 11, BT second terminal 12, PS first terminal 13, and PS second terminal 14). The positive electrode 2p of the battery 2 is connected to the BT first terminal 11. The negative electrode 2n of the battery 2 is connected to the BT second terminal 12. The positive electrode 3p of the DC power source 3 is connected to the PS first terminal 13. The negative electrode 3n of the DC power source 3 is connected to the PS second terminal 14. Note that BT is an abbreviation for Battery. PS is an abbreviation for Power Source. The dotted arrow lines in FIG. 1 represent signal lines.

The BT first terminal 11 and the PS first terminal 13 are connected by a first power line 15. The BT second terminal 12 and the PS second terminal 14 are connected by a second power line 16. A noise removal capacitor 19 is connected between the first power line 15 and the second power line 16.

The first power line 15 and the second power line 16 pass through an earth leakage detector 20. The earth leakage detector 20 includes a cutoff switch 24 that cuts off the first power line 15 and the second power line 16. When the sum of the current flowing through the first power line 15 and the current flowing through the second power line 16 is other than zero, the earth leakage detector 20 interrupts the first power line 15 and the second power line 16. Note that the direction of the current passing through the earth leakage detector 20 is determined. The direction of flow from the DC power source to the battery is considered positive. The direction of flow from the battery to the DC power source may be positive. When a predetermined current flows from the DC power source 3 to the battery 2 in the first power line 15 and a current of the same magnitude flows in the opposite direction in the second power line 16, the sum of the currents flowing in the first power line 15 and the second power line 16 is It becomes zero. When the magnitude (absolute value) of the current flowing through the first power line 15 and the magnitude (absolute value) of the current flowing through the second power line 16 are different, the earth leakage detector 20 interrupts the first power line 15 and the second power line 16.

The structure of the earth leakage detector 20 will be explained. The earth leakage detector 20 has a ring core 21 made of a magnetic material. The first power line 15 and the second power line 16 pass through the ring core 21. A magnetoelectric conversion element 22 is embedded in the ring core 21. When a current flows through the first power line 15 or the second power line 16, magnetic flux is generated inside the ring core 21. The magnetoelectric conversion element 22 detects the magnetic flux generated in the ring core 21. The measured value of the magnetoelectric conversion element 22 is sent to the sensor controller 23. When the measured value of the magnetoelectric conversion element 22 is other than zero, the sensor controller 23 opens the cutoff switch 24 to cut off the first power line 15 and the second power line 16. Note that a dead zone within a predetermined range including zero is set in the sensor controller 23. When the measured value of the magnetoelectric conversion element 22 deviates from the dead zone, the sensor controller 23 determines that the measured value of the magnetoelectric conversion element 22 is other than zero.

When the sum of the currents flowing through the first power line 15 and the second power line 16 is zero, that is, when currents of the same magnitude and opposite direction flow through the first power line 15 and the second power line 16, the currents caused by the respective currents flow. The magnetic fluxes generated in the ring core 21 cancel each other out. That is, when the sum of the currents flowing through the first power line 15 and the second power line 16 is zero (when currents of the same magnitude and opposite direction flow through the first power line 15 and the second power line 16), the ring core 21 appears to be No magnetic flux is generated. Therefore, when the sum of the currents flowing through the first power line 15 and the second power line 16 is zero, the cutoff switch 24 remains closed. When the sum of the currents flowing through the first power line 15 and the second power line 16 is not zero (when the magnitude of the current flowing through the first power line 15 and the second power line 16 is different), the sensor controller 23 opens the cutoff switch 24, The first power line 15 and the second power line 16 are cut off. If a leakage occurs in either the first power line 15 or the second power line 16, the sum of the currents flowing in the first power line 15 or the second power line 16 will not be zero. Then, the cutoff switch 24 is opened. That is, the first power line 15 and the second power line 16 are cut off.

The charging device 10 is equipped with a bypass power line 17. The bypass power line 17 bypasses the earth leakage detector 20 (does not pass through the earth leakage detector 20) and connects the PS first terminal 13 and the BT second terminal 12. A negative electrode 2n of the battery 2 is connected to the BT second terminal 12. That is, the bypass power line 17 connects the negative electrode 2n of the battery 2 and the PS first terminal 13. The bypass power line 17 is equipped with a switch 31.

The charging device 10 includes a controller 30. Controller 30 controls main relay 32 and switch 31. Further, the controller 30 communicates with the host controller 4. When the controller 30 receives a charging command from the host controller 4, it performs an earth leakage detector test. The controller 30 closes the main relay 32 after confirming that the earth leakage detector is normal. Then, the controller 30 connects the DC power source 3 to the battery 2. That is, charging is started.

When the controller 30 receives a charging command from the host controller 4, it performs the following process (earth leakage detector test). That is, controller 30 confirms that main relay 32 is open. In other words, the controller 30 disconnects the DC power source 3 from the PS first terminal 13 and the PS second terminal 14. Note that the battery 2 is maintained connected to the BT first terminal 11 and the BT second terminal 12. Further, the controller 30 closes the switch 31. Then, the controller 30 connects the PS first terminal 13 and the BT second terminal 12 (i.e., the negative electrode 2n) through the bypass power line 17. The thick arrow line in FIG. 1 shows the current flow at this time. The current flows from the positive electrode 2p of the battery 2 to the negative electrode 2n of the battery 2 through the BT first terminal 11, the first power line 15, the PS first terminal 13, the bypass power line 17, and the BT second terminal 12. At this time, as shown in FIG. 1, current flows through the first power line 15, but no current flows through the second power line 16. Therefore, if the earth leakage detector 20 is normal, the earth leakage detector 20 is activated and the cutoff switch 24 is opened. That is, the first power line 15 and the second power line 16 are cut off.

Although not shown, the charging device 10 is equipped with a check circuit that checks whether the cutoff switch 24 is open. The controller 30 can detect that the cutoff switch 24 has opened upon receiving a signal from the check circuit. When the controller 30 confirms that the cutoff switch 24 is opened as a result of the earth leakage detector test (i.e., if the earth leakage detector 20 operates normally), it opens the switch 31. The controller 30 then disconnects the bypass power line 17. The controller 30 restores the earth leakage detector 20 (closes the cutoff switch 24 to its original state). Then, the controller 30 closes the main relay 32 and starts charging the battery 2.

The thick arrow line in FIG. 2 indicates the flow of current during charging. The current flows from the positive electrode 3p of the DC power source 3 to the positive electrode 2p of the battery 2 through the PS first terminal 13, the first power line 15, and the BT first terminal 11. Further, the negative electrode 2n of the battery 2 is electrically connected to the negative electrode 3n of the DC power source 3 through the BT second terminal 12, the second power line 16, and the PS second terminal 14.

If no leakage occurs during charging, currents of the same magnitude and in opposite directions flow through the first power line 15 and the second power line 16. That is, the sum of the currents flowing through the first power line 15 and the second power line 16 becomes zero. The cutoff switch 24 is held closed.

If a leakage occurs while charging the battery 2, the earth leakage detector 20 is activated. Then, the cutoff switch 24 opens. That is, the first power line 15 and the second power line 16 are cut off. When the controller 30 detects that the cutoff switch 24 is opened, that is, when it detects the operation of the earth leakage detector 20, it sends a signal (earth leakage occurrence notification signal) to the host controller 4 to notify that an earth leakage has occurred.

If the cutoff switch 24 does not open even after the earth leakage detector test is performed, that is, if the earth leakage detector 20 does not operate, the controller 30 sends a signal notifying the occurrence of a malfunction (a malfunction notification signal) to the host controller 4. The controller 30 then ends the process. That is, if the earth leakage detector 20 is not activated, the controller 30 stops charging the battery 2 by the DC power source 3.

As shown in FIGS. 1 and 2, the charging device 10 can perform an earth leakage detector test with a simple configuration.

Points to note regarding the charging device 10a of the first embodiment will be described. The BT first terminal 11, the BT second terminal 12, the PS first terminal 13, and the PS second terminal 14 are respectively corresponds to the battery-side first terminal, the battery-side second terminal, the power source-side first terminal, and the power source-side second terminal. A positive electrode 2p and a negative electrode 2n of the battery 2 correspond to the first and second electrodes of the battery, respectively. A positive electrode 3p and a negative electrode 3n of the DC power source 3 correspond to the first and second poles of the power source, respectively. In FIGS. 1 and 2, the positive electrode 2p of the battery 2 is connected to the BT first terminal 11. In FIGS. 1 and 2, the positive electrode 3p of the DC power source 3 is connected to the PS first terminal 13. The negative electrode 2n of the battery 2 may be connected to the BT first terminal 11. The negative electrode 3n of the DC power source 3 may be connected to the PS first terminal 13.

### Second Embodiment

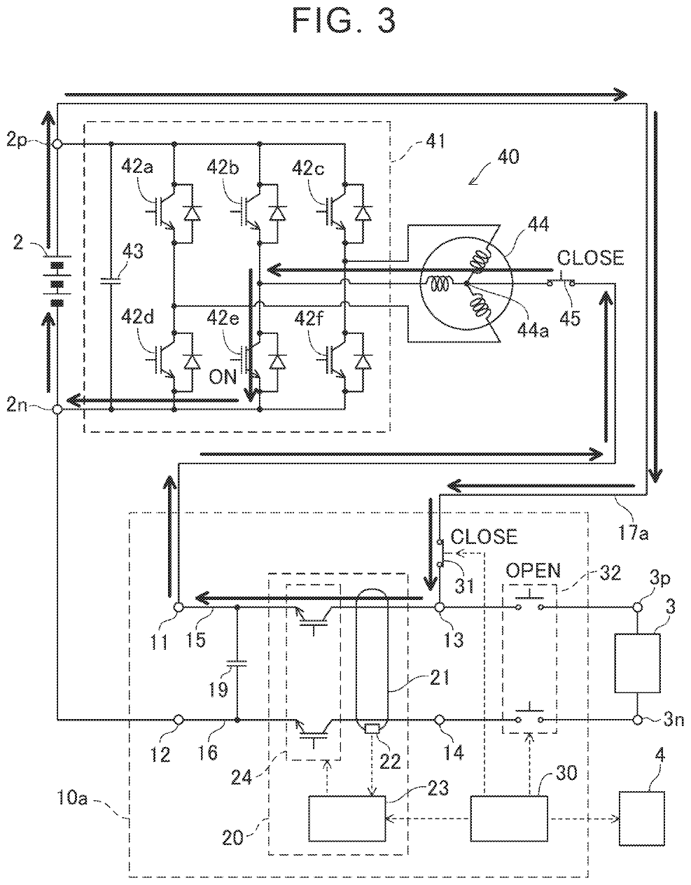

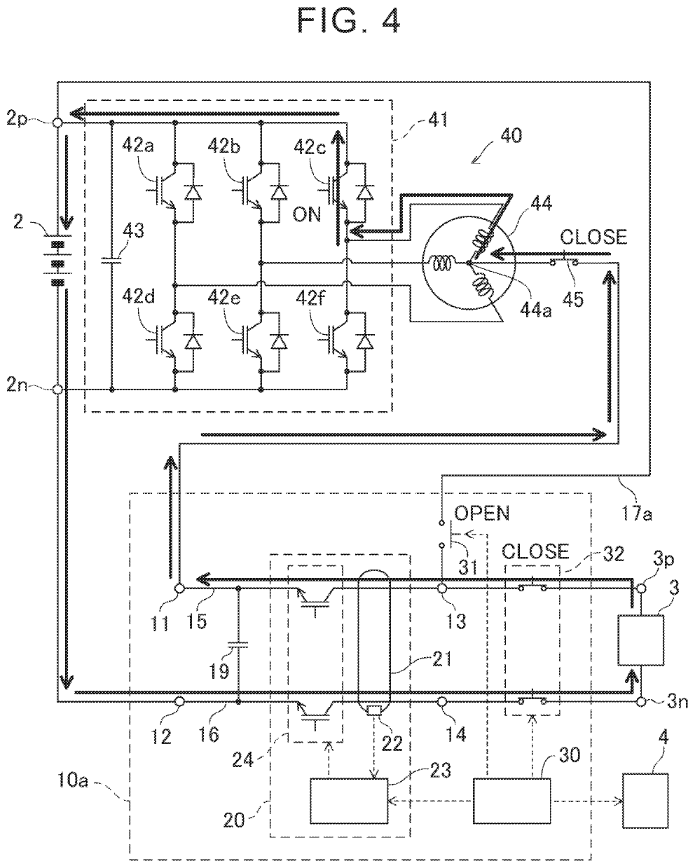

A charging device 10a according to a second embodiment will be explained with reference to FIGS. 3 and 4. The charging device 10a is mounted on a battery electric vehicle 40. FIGS. 3 and 4 are circuit diagrams of a battery electric vehicle 40 including the charging device 10a. The thick arrow line in FIG. 3 indicates the flow of current during the earth leakage detector test. The thick arrow line in FIG. 4 indicates the flow of current during battery charging.

The battery electric vehicle 40 includes a battery 2, an inverter 41, and an electric motor 44 for driving. DC power output from battery 2 is supplied to inverter 41. The inverter 41 includes six switching elements 42a to 42f. Two of the six switching elements 42a to 42f are connected in series. The inverter 41 includes three sets of series-connected bodies of two switching elements. The switching elements 42a to 42c on the high potential side of the series connection body are sometimes called upper arm switching elements. The switching elements 42d to 42f on the low potential side are sometimes called lower arm switching elements.

The three series connected bodies are connected in parallel between the positive electrode 2p and the negative electrode 2n of the battery 2. A noise removal capacitor 43 is also connected between the positive electrode 2p and the negative electrode 2n of the battery 2. When a controller (not shown) of the battery electric vehicle turns each of the six switching elements 42a to 42f on and off as appropriate, alternating current is output from the midpoint of each of the three series-connected bodies. Inverter 41 outputs three-phase alternating current.

The electric motor 44 is a three-phase AC motor and includes three coils. Three-phase alternating current flows through three coils. The three coils are star connected. One end of each of the three coils is connected at a midpoint 44a.

The charging device 10a is mounted on a battery electric vehicle 40. The charging device 10a is used when connecting the DC power source 3 outside the battery electric vehicle 40 to charge the battery 2. The charging device 10a of the second embodiment differs from the charging device 10 of the first embodiment in the wiring of the bypass power line 17a. The bypass power line 17a connects the PS first terminal 13 and the positive electrode 2p of the battery 2. A switch 31 is arranged in the middle of the bypass power line 17a.

As shown in FIG. 3, the bypass power line 17a connects the PS first terminal 13 to the positive electrode 2p of the battery 2 without passing through the earth leakage detector 20. In other words, the bypass power line 17a bypasses the earth leakage detector 20 and connects the PS first terminal 13 to the positive electrode 2p of the battery 2. The other configuration of the charging device 10a is the same as the configuration of the charging device 10 of the first embodiment.

The BT first terminal 11 is connected to the midpoint 44a of the electric motor 44. When performing the earth leakage detector test, at least one of the lower arm switching elements 42d to 42f of the inverter 41 is turned on (conducting state), and the remaining switching elements are turned off (interrupting state). In the case of FIG. 1, the lower arm switching element 42e is kept on (conducting state), and the remaining switching elements 42a to 42d and 42f are kept off (blocking state). Then, the midpoint of the electric motor 44 is electrically connected to the negative electrode 2n of the battery 2. Eventually, the BT first terminal 11 is connected to the negative electrode 2n of the battery 2.

When performing the earth leakage detector test and charging, the connection switch 45 located between the midpoint 44a of the electric motor 44 and the charging device 10a is closed. Naturally, the battery electric vehicle 40 is prohibited from running during the earth leakage detector test and charging.

As in the case of the charging device 10 of the first embodiment, the controller 30 opens the main relay 32 when receiving a charging command from the host controller 4. Then, the controller 30 closes the switch 31. That is, the controller 30 disconnects the DC power source 3 from the PS first terminal 13 and the PS second terminal 14. Then, the controller 30 connects the PS first terminal 13 and the positive electrode 2p of the battery 2 through the bypass power line 17a. The battery 2 is connected to a BT first terminal 11 and a BT second terminal 12. As described above, the BT first terminal 11 is connected to the negative electrode 2n of the battery 2 through the midpoint 44a of the electric motor 44 and the inverter 41 (switching element 42e).

The thick arrow line in FIG. 3 indicates the flow of current during the earth leakage detector test. The charging device 10a is connected to the battery 2 to form a closed circuit. The current output from the positive electrode 2p of the battery 2 returns to the negative electrode 2n of the battery 2 through the bypass power line 17a, the PS first terminal 13, the first power line 15, the BT first terminal 11, the midpoint 44a, and the switching element 42e.

During the earth leakage detector test, the first power line 15 connects the PS first terminal 13 to the BT first terminal 11, and the BT first terminal 11 is electrically connected to the negative electrode 2n of the battery 2. The bypass power line 17a connects the PS first terminal 13 to the positive electrode 2p of the battery 2. Therefore, at this time, the negative electrode 2n corresponds to the first electrode of the battery 2. The positive electrode 2p corresponds to the second electrode of the battery 2. The bypass power line 17a connects the second pole of the battery 2 to the PS first terminal 13 (power source-side first terminal).

As shown in FIG. 3, at this time, current flows through the first power line 15, but no current flows through the second power line 16. Therefore, if the earth leakage detector 20 is normal, the earth leakage detector 20 will operate. Then, the cutoff switch 24 opens. That is, the first power line 15 and the second power line 16 are cut off. If the cutoff switch 24 opens as a result of the earth leakage detector test (that is, if the earth leakage detector 20 operates normally), the controller 30 disconnects the bypass power line 17a. The controller 30 restores the earth leakage detector 20 (closes the cutoff switch 24). Then, the controller 30 closes the main relay 32 and starts charging the battery 2. On the other hand, if the cutoff switch 24 does not open as a result of the earth leakage detector test (that is, the earth leakage detector 20 does not operate), the controller 30 sends a signal notifying the occurrence of a malfunction (failure notification signal) to the host controller 4, and ends the process. That is, if the earth leakage detector 20 does not operate in the earth leakage detector test, the controller 30 stops charging the battery 2 by the DC power source 3.

When the battery 2 is being charged, the controller 30 turns on at least one of the upper arm switching elements 42a to 42c (conducting state) and keeps the remaining switching elements off (blocking state). In the case of FIG. 4, the controller 30 turns on the upper arm switching element 42c (conducting state) and keeps the remaining switching elements 42a, 42b, 42d to 42f off (blocking state). As shown in FIG. 4, the current output from the positive electrode 3p of the DC power source 3 passes through the PS first terminal 13, the first power line 15, the BT first terminal 11, the midpoint 44a, and the switching element 42c to flow to the positive electrode 2p of the battery 2. The negative electrode 2n of the battery 2 is electrically connected to the negative electrode 3n of the DC power source 3 through the BT second terminal 12, the second power line 16, and the PS second terminal 14.

The structure of the charging device 10a of the second embodiment is basically the same as the structure of the charging device 10 of the first embodiment. Earth leakage detector tests can be performed with a simple configuration. The charging device 10a of the second embodiment charges the battery 2 through the electric motor 44 and inverter 41 of the battery electric vehicle. Therefore, during charging, leakage in the circuit including the electric motor 44 and the inverter 41 can be detected.

Points to note regarding the techniques described in the examples will be described. The charging device disclosed in this specification may include one of a bypass power line 17 that bypasses the earth leakage detector 20 and connects the BT second terminal 12 and the PS first terminal 13, and a bypass power line 17a that connects the PS first terminal 13 and the negative electrode 2n (second electrode) of the battery 2 without passing through the earth leakage detector 20.

In either the first embodiment or the second embodiment, the positive electrode 2p and negative electrode 2n of the battery 2 may be replaced. In either the first embodiment or the second embodiment, the positive electrode 3p and negative electrode 3n of the DC power source 3 may be replaced.

The DC power source 3 is a power source for charging the battery 2. Therefore, the DC power source 3 may be referred to as a power supply device.

In the circuit of FIG. 4, it is also possible to boost the power of the DC power source 3 and supply it to the battery 2. That is, the coil (stator coil) of the electric motor 44 and the switching elements 42a to 42f of the inverter 41 can constitute a boost converter. Here, for convenience of explanation, among the six switching elements 42a to 42f of the inverter 41, the switching elements 42a, 42b, and 42c connected to the positive electrode 2p of the battery 2 are referred to as upper arm switching elements. Furthermore, among the six switching elements 42a to 42f of the inverter 41, the switching elements 42d, 42e, and 42f connected to the negative electrode 2n are referred to as lower arm switching elements. The controller 30 holds any one of the lower arm switching elements on for a short period of time. The controller 30 then holds the remaining switching elements off. Electrical energy is then stored in the coil of the electric motor 44. Subsequently, the controller 30 switches the lower arm switching element from on to off. The controller 30 then switches at least one upper arm switching element from off to on. The electrical energy stored in the coil is released. The electromotive force of the coil pushes up the voltage between the positive electrode 3p of the DC power source 3 and the positive electrode 2p of the battery 2. By appropriately selecting the time during which the lower arm switching element is held on and the time during which the upper arm switching element is held on, the voltage of the DC power source 3 can be increased and supplied to the battery 2.

Specific examples of the present disclosure have been described above in detail. These are examples only. They are not intended to limit the scope of the claims. The techniques described in the claims include various modifications and alterations of the specific examples illustrated above. The technical elements described in the present specification or the drawings exhibit technical usefulness alone or in various combinations, and are not limited to the combinations described in the claims at the time of filing. Furthermore, the techniques illustrated in this specification or the drawings can simultaneously achieve multiple objectives. The techniques illustrated in this specification or drawings have technical utility in and of themselves by achieving one of the objectives.

What is claimed is:

1. A charging device comprising:
a battery-side first terminal to which a first electrode of a battery is connected;
a battery-side second terminal to which a second electrode of the battery is connected;
a power source-side first terminal to which a first electrode of a power source is connected;
a power source-side second terminal to which a second electrode of the power source is connected;
a first power line connecting the battery-side first terminal and the power source-side first terminal;
a second power line connecting the battery-side second terminal and the power source-side second terminal;
an earth leakage detector through which the first power line and the second power line pass, shuts off the first power line and the second power line when a sum of a current flowing through the first power line and a current flowing through the second power line is other than zero;
a bypass power line that bypasses the earth leakage detector and connects the second electrode of the battery and the power source-side first terminal; and
a controller, wherein the controller
disconnects the power source from the power source-side first terminal and the power source-side second terminal, and connects the power source-side first terminal and the second electrode of the battery through the bypass power line,
when the earth leakage detector operates, disconnects the bypass power line, restores the earth leakage detector, and connects the power source to the power source-side first terminal and the power source-side second terminal to start charging the battery, and
when the earth leakage detector does not operate, stops charging the battery by the power source.
